(19) United States
(12) Patent Application Publication
(10) Pub. No.: US 2019/0305387 A1
(43) Pub. Date: Oct. 3, 2019

(54) High-Voltage Battery for a Motor Vehicle, in Particular a Car

(71) Applicant: Bayerische Motoren Werke Aktiengesellschaft, Muenchen (DE)

(72) Inventors: Christoph BORN, Muenchen (DE); Christian KULP, Muenchen (DE); Arne MENCK, Muenchen (DE); Sebastian PAUL, Muenchen (DE); Jan Philipp SCHMIDT, Muenchen (DE); Benno SCHWEIGER, Muenchen (DE); Werner SELIGER, Hallbergmoos (DE); Jens VETTER, Hebertshausen (DE); Hermann ZEHENTNER, Hohenpolding (DE); Dieter ZIEGLTRUM, Vaterstetten (DE)

(21) Appl. No.: 16/444,040

(22) Filed: Jun. 18, 2019

Related U.S. Application Data
(63) Continuation of application No. PCT/EP2017/080447, filed on Nov. 27, 2017.

(30) Foreign Application Priority Data
Dec. 20, 2016 (DE) 10 2016 225 691.2

(51) Int. Cl. H01M 10/48; G01R 31/374; H01M 10/42; H02J 7/00; B60R 16/03

(52) U.S. Cl. CPC H01M 10/486; G01R 31/374; H01M 10/482; H01M 2220/20; H02J 7/0021; B60R 16/03; H01M 2200/10; H01M 10/4207

(57) ABSTRACT

A high-voltage battery for a motor vehicle has at least one battery cell for storing electrical energy and at least one temperature sensor, by which a temperature of the battery cell can be detected. The temperature sensor is arranged within the battery cell.

### CROSS REFERENCE TO RELATED APPLICATIONS

This application is a continuation of PCT International Application No. PCT/EP2017/080447, filed Nov. 27, 2017, which claims priority under 35 U.S.C. § 119 from German Patent Application No. 10 2016 225 691.2, filed Dec. 20, 2016, the entire disclosures of which are herein expressly incorporated by reference.

### BACKGROUND AND SUMMARY OF THE INVENTION

The invention relates to a high-voltage battery and to a motor vehicle having such a battery.

High-voltage batteries of this type for motor vehicles, in particular for cars, are already sufficiently known from the prior art, specifically from the mass production of vehicles. A high-voltage battery of this type is also designated as an HV battery, wherein electrical energy or electric current can be stored by means of said high-voltage battery. To this end, the high-voltage battery comprises at least one battery cell for the storage of electrical energy. Customarily, the high-voltage battery comprises a plurality of battery modules, each of which comprises a plurality of electrically interconnected battery cells. Customarily, the battery modules or battery cells are connected in series, in order to permit the achievement of a particularly high electrical voltage, specifically a particularly high electrical operating voltage, in the high-voltage battery. This permits the achievement of high electrical capacities, by means of which the respective motor vehicle can be propelled.

The high-voltage battery is a high-voltage component, the electrical voltage of which, specifically the electrical operating voltage, is customarily substantially greater than 50 volts, and specifically greater than 100 volts. Customarily, the electrical voltage of the high-voltage component is several hundred volts (V), such that particularly high electrical capacities can be achieved for the propulsion of the respective motor vehicle.

The respective motor vehicle is customarily conFIGUREd as a hybrid or electric vehicle, and includes at least one electrical machine, by which the motor vehicle can be driven. The electrical machine can be operated in a motor mode for this purpose. In order to operate the electrical machine in motor mode, and thus as an electric motor for the propulsion of the motor vehicle, the electrical machine is supplied with electrical energy or electric current which is stored in the high-voltage battery.

The high-voltage battery further includes at least one temperature sensor, by which a temperature of the battery cell is detectable. The temperature detected by the temperature sensor is employed for the operation of the high-voltage battery, on the basis of the temperature thus detected. Accordingly, a particularly accurate detection of temperature is desirable.

The object of the present invention is therefore the further development of a high-voltage battery and a motor vehicle of the above-mentioned type, such that the temperature of the battery cell can be detected in a particularly accurate manner.

According to the invention, this object is achieved by a high-voltage battery according to the claimed invention as well as by a motor vehicle having such a high-voltage battery.

A first aspect of the invention relates to a high-voltage battery for a motor vehicle, specifically for a car such as, for example, a private car. The high-voltage battery is also described as an HV battery, a high-voltage store or an HV store and, for example, has an electrical voltage, specifically an electrical operating voltage, greater than 50 volts (V), specifically greater than 100 volts. Preferably, the high-voltage battery has an electrical voltage of several hundred volts (V), in order to permit the achievement of particularly high electrical capacities. By means of or in the high-voltage battery, electrical energy or electric current can be stored. To this end, the high-voltage battery includes at least one battery cell for the storage of electrical energy. The high-voltage battery preferably has a plurality of battery modules, each of which comprises a plurality of battery cells. The battery cells of the respective battery module are electrically interconnected, wherein the battery cells, for example, are connected in series. Moreover, the battery modules are electrically interconnected, wherein the battery modules, for example, are connected in series. The high-voltage battery moreover includes at least one temperature sensor, by which the temperature of the battery cell is detectable.

According to the invention, in order to permit the particularly accurate detection of the temperature of the battery cell, it is provided that the temperature sensor is arranged within the battery cell. In the context of the invention, the temperature of the battery cell is customarily measured by way of a temperature sensor, also described as a temperature probe, which is connected, for example, via at least one cable or at least one conductive element to an electronic computing unit. The temperature sensor can deliver at least one signal, for example an electrical signal, which is characteristic of the temperature, which is detected or measured by way of the temperature sensor which is transmitted to the electronic computing unit, specifically via the conductive element, and is received by the electronic computing unit. It is thus possible, for example, for the electrical evaluation of the temperature probe to be executed. If the high-voltage battery has a plurality of temperature sensors, a corresponding number of channels, via which the respective signal can be transmitted, and a corresponding number of evaluation units will be required. Customarily, moreover, a geometric path which heat is required to follow, for example, from the interior of the battery cell to the temperature sensor, cannot be detected by analysis, such that software approximation models are employed, in order to calculate, from the temperature which is measured by the temperature sensor and which constitutes a measured temperature value, an “internal cell temperature” which prevails, for example, in the interior of the battery cell.

Customarily, the temperature sensor is arranged externally to the battery cell or, where applicable, on the battery cell, such that customarily, for example, by means of the temperature sensor, a temperature is measured which prevails on an outer side of the battery cell, but not in the interior of the battery cell. It is, however, desirable to obtain information on the prevailing temperature in the interior of the battery cell, in order, for example, to achieve the exceptionally secure operation of the high-voltage battery. The temperature measured by the temperature sensor is employed, for example, in the execution of an operating strategy for the high-voltage battery which is based upon the temperature measured by means of the temperature sensor, such that the high-voltage battery is operated, for example, as a function of the temperature which is measured by the temperature sensor.

Given that, according to the invention, the temperature sensor is arranged within the battery cell, it is possible, for example, for a temperature prevailing within the battery cell, and specifically in the interior of the battery cell, to be measured, at least essentially, in a direct manner, or for such a temperature prevailing in the interior of the battery cell to be detected in a particularly accurate manner, such that a particularly advantageous and secure operation of the high-voltage battery is achievable. If, for example, by means of the temperature sensor, it is detected that the temperature detected by the temperature sensor exceeds a stipulated limiting value, corresponding measures can be implemented in order to prevent any undesirable effects associated with an inordinately high temperature in the battery cell, or to restrict said effects within a limited scope. Moreover, in conventional high-voltage batteries, it is provided that not all the temperatures of all the battery cells are measured, but that measurements are only taken in specific locations at or on the battery cells or battery modules. By the arrangement of the temperature sensor in the battery cell, it is thus possible, in a conceivably favorable manner, to obtain information on any temperature in each battery cell, such that a particularly advantageous and secure operation of the high-voltage battery is achievable.

It has been observed that, in a conventional high-voltage battery, the customary positioning of the temperature sensor outside the battery cell is associated with systematic measuring errors. In the high-voltage battery according to the invention, this can now be avoided. Moreover, customarily, only a time-delayed measurement of temperature is achieved, and the temperature measurement is influenced by cooling, which can now be avoided in the high-voltage battery according to the invention. Moreover, the detection of temperature is customarily dependent upon the geometry of the battery cell of the battery module, which again can now be avoided.

It has proved to be particularly advantageous if the battery cell has a housing having at least one location space. It is thus advantageously provided that the temperature sensor is accommodated in the location space or within the housing, rather than in a wall of the housing. The temperature can thus be detected in a particularly accurate manner.

In a particularly advantageous embodiment of the invention, an electrolyte of the battery cell is accommodated in the location space. The temperature sensor is also accommodated in the same location space in which the electrolyte is accommodated. The temperature in the interior of the battery cell can thus be detected in a particularly accurate and reliable manner, such that a particularly advantageous operation of the high-voltage battery can be realized.

A further embodiment is characterized in that the battery cell includes at least one electrode, which is arranged in the location space, wherein the temperature sensor is arranged in the location space. In other words, the electrode and the temperature sensor are arranged in the same location space within the battery cell, specifically within the housing, such that the prevailing temperature in the interior of the battery cell can be detected in a particularly accurate manner.

In a further advantageous configuration of the invention, at least a part of the temperature sensor is arranged on the electrode. Thus, for example, the temperature of the electrode, at least essentially, can be recorded directly, such that a particularly advantageous temperature detection and, in consequence, a particularly advantageous and secure operation of the high-voltage battery are achievable.

In a particularly advantageous embodiment of the invention, at least a part of the temperature sensor is conFIGUREd as a coating of the electrode. Particularly limited spatial requirements are achievable as a result wherein, simultaneously, a particularly advantageous and, at least essentially, direct measurement of the temperature of the battery cell, and specifically of the electrode, can be achieved.

Customarily, the temperature sensor has at least one thermal conductor for the detection of temperature, wherein the thermal conductor is also described as NTC, an NTC resistor or an NTC thermistor (NTC: Negative Temperature Coefficient). However, it has proved to be particularly advantageous if the temperature sensor includes at least one oscillating circuit, by means of which the temperature can be detected by reference to the detuning of the oscillating circuit associated with the action of temperature. Preferably, the temperature sensor does not comprise any NTC resistor. The above-mentioned oscillating circuit is an electrical oscillating circuit, which is a resonant electrical circuit comprising at least one coil and at least one capacitor, wherein the resonant electrical circuit can execute electrical oscillations, specifically at a defined frequency, specifically a resonant frequency. The oscillating circuit is detuned by the action of temperature, as a result of which a detuning or variation of the frequency occurs. Accordingly, for example, by the detection of frequency, and thus by reference to the frequency, the temperature in the interior of the battery cell can be deduced. For example, the temperature influences the coil, and thus an inductance of the oscillating circuit, and/or the capacitor, and thus a capacitance of the oscillating circuit, as a result of which, in turn, the resonant frequency is influenced.

The inductance or coil and/or the capacitor or the capacitance do not necessarily need to be constituted by a discrete electrical component, but can be the effect of at least one other component of the battery cell. In other words, it is preferably provided that the coil and/or the capacitor of the oscillating circuit is constituted by a component of the battery cell. As a result, both the number of components and the structural space can be particularly restricted wherein, simultaneously, the temperature can be detected in a particularly accurate manner.

It is further contemplated that the detuning of the oscillating circuit results from a detuning of the dielectric constant of the capacitor. In other words, the above-mentioned detuning can be a detuning of the dielectric constant of the capacitor. If this results in a temperature variation, there is a resulting variation, and thus a detuning of the dielectric constant of the capacitor, as a result of which a detuning or variation in frequency occurs. If this variation in frequency is detected, it is possible, by reference to the detection of frequency, to deduce the variation in temperature. For example, the frequency corresponds to the temperature such that, on the basis of the frequency, the temperature in the battery cell can be detected.

The detuning of the frequency, specifically of the mid-frequency, of the oscillating circuit is measured, for example, via at least one pole of the battery cell, by the application of an external frequency, specifically to said pole. No interference proceeds from serial interconnection. By this arrangement, moreover, a temperature distribution, specifically in the battery cell, can be measured such that, for example, a minimum temperature, a maximum temperature and an average temperature of the battery cell can measured or detected, specifically directly.

In order to permit the particular restriction of the number of parts, weight and costs, and thus simultaneously achieve a particularly accurate temperature measurement, it is provided, in a further embodiment of the invention, that the component of the battery cell is a coating or an electrode film of the battery cell.

A second aspect of the invention relates to a motor vehicle, specifically an automobile, having at least one high-voltage battery according to the invention. Advantages and advantageous configurations of the first aspect of the invention are to be considered as advantages and advantageous configurations of the second aspect of the invention, and vice versa.

Other objects, advantages and novel features of the present invention will become apparent from the following detailed description of one or more preferred embodiments when considered in conjunction with the accompanying drawing.

### BRIEF DESCRIPTION OF THE DRAWING

FIG. 1 is a schematic sectional view of a high-voltage battery for a motor vehicle, having at least one battery cell for the storage of electrical energy, and having at least one temperature sensor, by which a temperature of the battery cell is detectable, wherein the temperature sensor is arranged within the battery cell.

### DETAILED DESCRIPTION OF THE DRAWING

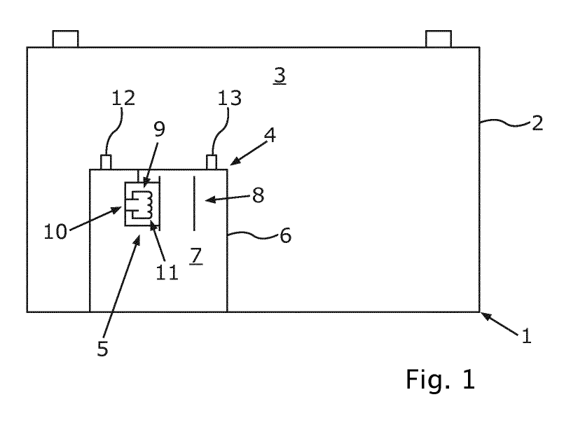

The single FIG. 1 is a schematic sectional view of a high-voltage battery for a motor vehicle, which is identified overall by the number 1. The high-voltage battery 1 is also described as an HV battery, an energy store or a high-voltage energy store (HV energy store), and has an electrical voltage, specifically an electrical operating voltage, substantially greater than 50 volts (V), specifically greater than 100 V. Specifically, the high-voltage battery 1 has an electrical operating voltage of several hundred volts, in order to permit the achievement of particularly high electrical capacities for the propulsion of the motor vehicle. The motor vehicle is, for example, an electric or hybrid vehicle, having at least one electrical machine, by which the motor vehicle can be propelled. To this end, the electrical machine is operable in a motor mode, and thus as an electric motor. By means of the high-voltage battery 1 or in the high-voltage battery 1, electrical energy or electric current can be stored. In order to operate the electrical machine in motor mode, the electrical machine is supplied with electrical energy which is stored in the high-voltage battery 1.

From FIG. 1, it can be seen that the high-voltage battery 1 has a housing 2 with a location space 3. In the location space 3, and thus in the housing 2, at least one battery cell of the high-voltage battery, which is identified overall by the number 4, is arranged, wherein, by means of or in the battery cell 4, electrical energy or electric current can be stored. Preferably, it is provided that the high-voltage battery 1 comprises a plurality of battery modules, which are not represented in greater detail in the FIGURE, which are electrically interconnected, and can thus be specifically connected in series. The respective battery module comprises, for example, a plurality of battery cells, which are electrically interconnected and can, for example, be connected in series. The preceding remarks with respect to the battery cell 4 and the battery module thereof, and those provided hereinafter, are automatically applicable to the other battery modules, and the battery cells thereof, which are not further represented in the FIGURE.

The high-voltage battery 1, specifically the battery cell 4, includes at least one temperature sensor 5, by which a temperature of the battery cell 4 is detectable. During the operation of the high-voltage battery 1, the temperature sensor 5 delivers, for example, specifically at least one electrical signal, which is characteristic of the temperature detected by way of the temperature sensor 5. The signal is transmitted, for example, to an electronic computing unit, specifically of the high-voltage battery 1, which is not further represented in the FIGURE, and is received by the electronic computing unit. By means of the electronic computing unit, the high-voltage battery 1 can be operated, and specifically regulated, as a function of the temperature detected, such that, for example, on the basis of the temperature detected by the temperature sensor 5, an operating strategy for the control or regulation, i.e. for the operation of the high-voltage battery 1, is executed. Specifically, safety functions can be tripped on the basis of temperature. If it is determined, for example, that the temperature of the battery cell 4 exceeds a definable limiting value, measures can be implemented, for example, for the prevention of effects resulting from this excessive temperature, or at least for the restriction thereof within a limited scope. Undesirable critical states of the high-voltage battery 1 can be prevented accordingly.

In order to permit a particularly advantageous, and specifically secure operation of the high-voltage battery 1, the temperature sensor 5 is arranged within the battery cell 4. From the FIGURE, it can be seen that the battery cell 4 comprises a housing 6, which is also described as the cell housing. The cell housing delimits at least one location space 7 in which, for example, electrodes 8 of the battery cell 4 are accommodated. Alternatively or additionally, in the location space 7, a liquid electrolyte of the battery cell 4, which is not represented in greater detail in the FIGURE, is accommodated. The temperature sensor 5 is thus accommodated in the same location space 7 in which the electrodes 8 and/or the electrolyte are/is accommodated.

It is customarily provided that the temperature sensor 5 is accommodated outside the battery cell 4 and, for example, in the location space 3, wherein the temperature sensor 5, for example, is arranged on an outer side of the housing 6 which is averted from the location space 7. Accordingly, by way of a customary temperature sensor 5, a temperature prevailing on the outer side is customarily detected. In order to determine, for example, a temperature in the interior of the battery cell 4, for example on the basis of the prevailing temperature on the outer side, detected by the temperature sensor 5, the temperature in the interior of the battery cell 4 is inferred, specifically by back calculation. This calculation of the prevailing temperature in the interior of the battery cell 4 is, however, prone to error. This disadvantage can now be eliminated in that, by the arrangement of the temperature sensor 5 in the location space 7, the prevailing temperature in the interior of the battery cell 4, at least essentially, can be detected in a direct manner.

From the FIGURE it can be seen that, in the exemplary embodiment illustrated, the temperature sensor 5 is arranged on one of the electrodes 8. It is, for example, contemplated that at least a part of the temperature sensor 5 is conFIGUREd as a coating of the electrodes. It can further be seen that the temperature sensor 5 includes at least one electrical oscillating circuit 9 for the detection of temperature. By means of the oscillating circuit 9, the temperature of the battery cell 4 is detectable by reference to a detuning of the oscillating circuit 9 in response to the temperature of the battery cell 4. The oscillating circuit 9 comprises, for example, a capacitor 10 having a capacitance, and at least one coil 11 having an inductance.

The oscillating circuit 9 is a resonant electrical circuit comprised of the coil 11 and the capacitor 10, wherein the electrical circuit can generate electrical oscillations at a given frequency, specifically at a resonant frequency and/or a mid-frequency. The frequency is temperature-dependent such that, for example, variations in temperature will result in variations in the frequency. Consequently, as a function of the frequency at which the oscillating circuit oscillates, the prevailing temperature in the battery cell 4 can be deduced in a particularly accurate manner.

The coil 11 or the inductance thereof and/or the capacitor 10 or the capacitance thereof, do not necessarily need to be constituted by a discrete electrical component, but can be the effect of another component of the battery cell 4. In other words, for example, a component of the battery cell 4 which would be present in any event can be employed as the inductance or capacitance. The other component is, for example, an electrode film which constitutes at least one of the electrodes 8, or a coating, specifically of one of the electrodes 8. Detuning of the oscillating circuit 9 can involve, for example, a detuning of the dielectric constants or the permittivity of the capacitor 10. Detuning of the oscillating circuit 9 or the frequency is measured, for example, via at least one pole 12 or 13 of the battery cell, by the application of an external frequency to said pole 12 or 13, wherein no interference proceeds from serial interconnection. By the arrangement of the temperature sensor 5 in the battery cell 4, it is possible, for example, to measure a temperature distribution across the battery cell 4, at least indirectly.

### LIST OF REFERENCE NUMBERS

1 High-voltage battery
2 Housing
3 Location space
4 Battery cell
5 Temperature sensor
6 Housing
7 Location space
8 Electrodes
9 Oscillating circuit
10 Capacitor
11 Coil
12 Pole
13 Pole

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A high-voltage battery for a motor vehicle, comprising:
at least one battery cell for storing electrical energy; and
at least one temperature sensor, by which a temperature of the battery cell is detectable, wherein
the temperature sensor is arranged within the battery cell.

2. The high-voltage battery as claimed in claim 1, wherein
the battery cell comprises a housing having at least one location space.

3. The high-voltage battery as claimed in claim 2, wherein
an electrolyte of the battery cell and the temperature sensor are accommodated in the location space.

4. The high-voltage battery as claimed in claim 3, wherein
the battery cell comprises at least one electrode which is arranged in the location space, and
the temperature sensor is arranged in the location space.

5. The high-voltage battery as claimed in claim 4, wherein
at least a part of the temperature sensor is arranged on the electrode.

6. The high-voltage battery as claimed in claim 5, wherein
at least a part of the temperature sensor is conFIGUREd as a coating of the electrode.

7. The high-voltage battery as claimed in claim 2, wherein
the battery cell comprises at least one electrode which is arranged in the location space, and
the temperature sensor is arranged in the location space.

8. The high-voltage battery as claimed in claim 7, wherein
at least a part of the temperature sensor is arranged on the electrode.

9. The high-voltage battery as claimed in claim 8, wherein
at least a part of the temperature sensor is conFIGUREd as a coating of the electrode.

10. The high-voltage battery as claimed in claim 1, wherein
the temperature sensor comprises at least one oscillating circuit, by which the temperature is detectable by reference to detuning of the oscillating circuit associated with action of temperature.

11. The high-voltage battery as claimed in claim 10, wherein
a coil and/or a capacitor of the oscillating circuit is constituted by a component of the battery cell.

12. The high-voltage battery as claimed in claim 11, wherein
the component is a coating or an electrode film of the battery cell.

13. A motor vehicle, comprising at least one high-voltage battery as claimed in claim 1.
